(19) United States
(12) Patent Application Publication
(10) Pub. No.: US 2025/0125572 A1
(43) Pub. Date: Apr. 17, 2025

(54) ELECTRODE WITH ENGINEERED SURFACE FOR IMPROVED ENERGY PERFORMANCE

(71) Applicant: Cymer, LLC, San Diego, CA (US)

(72) Inventor: Edward Siqi Luo, San Diego, CA (US)

(21) Appl. No.: 18/689,610

(22) PCT Filed: Sep. 2, 2022
(86) PCT No.: PCT/US2022/042536

§ 371 Date: Mar. 6, 2024

Related U.S. Application Data
(60) Provisional application No. 63/247,558, filed on Sep. 23, 2021.

(51) Int. Cl. H01S 3/038

(52) U.S. Cl. CPC H01S 3/0385; H01S 3/0382

(57) ABSTRACT

One or both of the confronting discharge surfaces of the cathode and anode electrodes in a laser discharge chamber, that is, the surfaces between which the plasma is struck, are provided with an engineered surface structure forming distributed discharge initiation or nucleation sites in order to effect control over the discharge process.

### CROSS REFERENCE TO RELATED APPLICATIONS

This application claims priority to U.S. Application No. 63/247,558, filed Sep. 23, 2021, titled ELECTRODE WITH ENGINEERED SURFACE FOR IMPROVED ENERGY PERFORMANCE, which is incorporated herein in its entirety by reference.

### TECHNICAL FIELD

The present disclosed subject matter relates to laser-generated light sources such as are used for integrated circuit photolithographic manufacturing processes.

### BACKGROUND

In deep ultraviolet (“DUV”) laser sources, pulses of laser radiation are generated by causing a plasma discharge to occur between electrodes in a discharge chamber. These lasers are typically configured to generate sequences of pulses called bursts. One figure of merit for the operation of such chambers is the amount of laser energy generated as a function of the electrical voltage applied across the electrodes. For an efficient laser, there should be as much energy generated for a given potential difference between the electrodes as possible.

Another criterion for the performance of the laser chamber is the stability over time of energy production as a function of the voltage across the electrodes. In other words, it is generally desirable that the amount of energy generated by a given electrode voltage remain the same or as close to the same as possible over time. It is, however, generally expected that this functional relationship will change over long periods of time such as the chamber lifetime, so that a new laser chamber will be expected to exhibit an energy versus voltage relationship which is different from the energy versus voltage relationship the chamber can be expected to exhibit towards the end of its lifetime. There are instances, however, when the amount of energy generated for a given electrode voltage may vary over much shorter periods of time, and even within a burst of pulses. Indeed, a phenomenon has been observed in which the amount of energy produced for a given voltage difference falls off relatively quickly within a burst. This can lead to a lack of repeatability of manufacturing processes utilizing the bursts of laser energy such as semiconductor photolithography processes.

It is therefore desirable to be able to provide a laser chamber and, in particular, electrodes for a laser chamber in which this rapid falloff of the output energy as a function of applied electrical voltage is mitigated.

### SUMMARY

The following presents a concise summary of one or more embodiments in order to provide a basic understanding of the present invention. This summary is not an extensive overview of all contemplated embodiments and is not intended to identify key or critical elements of all embodiments nor delineate the scope of any or all embodiments. Its sole purpose is to present some concepts relating to one or more embodiments in a succinct form as a prelude to the more detailed description that is presented later.

According to one aspect of an embodiment, one or both of the confronting discharge surfaces of electrodes in the laser discharge chamber, that is, the surfaces between which the plasma is struck, are provided with an engineered surface structure providing distributed discharge initiation or nucleation sites in order to control the spatial uniformity of the discharge process.

According to an aspect of an embodiment there is disclosed an electrode for a laser discharge chamber, the electrode comprising an engineered discharge surface, the engineered discharge surface comprising a distribution of a plurality of engineered discharge nucleation sites. The engineered discharge surface may comprise a plurality of engineered indentations each having an edge and wherein each of the engineered nucleation sites may comprise at least a portion of the edge of each of the engineered indentations. The engineered discharge surface may comprise a plurality of engineered protrusions each having an edge and wherein each of the engineered nucleation sites may comprise at least a portion of the edge of each of the engineered protrusions. The engineered discharge surface may comprise a plurality of engineered tracks each having an edge and wherein each of the engineered nucleation sites may comprise at least a portion of the edge of each of the engineered tracks. The engineered indentations have a depth in the range of about 10 μm to about 1000 μm.

The engineered indentations may be formed by laser drilling, chemical etching, plasma etching, mechanical drilling, and/or mechanical indentation.

A first subset of the engineered discharge nucleation sites have a first shape and a second subset of the engineered discharge nucleation sites have a second subset shape different from the first subset shape.

The engineered indentations may be circular engineered indentations. The circular engineered indentations have a radius having a same length. A first subset of the circular engineered indentations may have a radius having a first subset length and a second subset of the circular engineered indentations may have a radius having a second subset length different from the first subset length. The circular engineered indentations have a radius in the range of about 10 μm to about 1000 μm. The circular engineered indentations may be arranged in a periodic arrangement with a center-to-center spacing in the range of about 10 μm to about 1000 μm.

The engineered discharge surface may have a periphery per unit area in a range of 1 mm⁻¹ to about 20 mm⁻¹.

The engineered indentations may be oblong engineered indentations. The oblong engineered indentations may be arranged in a periodic arrangement with a spacing in the lengthwise dimension in the range of about 10 μm to about 1000 μm.

The distribution of a plurality of engineered discharge nucleation sites may comprise an arrangement of engineered discharge nucleation sites. The arrangement may be periodic or random.

The engineered discharge nucleation sites have a first spacing in the lengthwise dimension of the discharge surface and a second spacing in the widthwise dimension of the discharge surface. The first spacing may be the same as the second spacing or the first spacing may be different from the second spacing.

According to another aspect of an embodiment there is disclosed a system for generating laser radiation comprising a discharge chamber, a first electrode positioned at least partially within the discharge chamber, and a second electrode positioned at least partially within the discharge chamber, the first electrode having a first discharge surface and the second electrode having a second discharge surface, the first discharge surface and the second discharge surface being arranged to confront one another across a gap, wherein at least one of the first discharge surface and the second discharge surface may comprise a distribution of a plurality of engineered discharge nucleation sites. The first electrode may be connected to function as a cathode and the first discharge surface may comprise the distribution of the plurality of engineered discharge nucleation sites. The first discharge surface may comprise a plurality of engineered indentations each having an edge and wherein each of the engineered nucleation sites may comprise at least a portion of the edge of each of the engineered indentations.

According to another aspect of an embodiment there is disclosed a method of making a discharge electrode for a laser discharge chamber, the method comprising providing an electrode having a discharge surface and creating a distribution of a plurality of engineered discharge nucleation sites on the discharge surface. Creating the distribution of a plurality of engineered discharge nucleation sites on the discharge surface may comprise laser drilling to form the engineered discharge nucleation sites, chemically etching to form the engineered discharge nucleation sites, plasma etching to form the engineered discharge nucleation sites, mechanically drilling to form the engineered discharge nucleation sites and/or mechanically indenting the engineered discharge nucleation sites.

Further embodiments, features, and advantages of the subject matter of the present disclosure, as well as the structure and operation of the various embodiments, are described in detail below with reference to the accompanying drawings.

### BRIEF DESCRIPTION OF THE DRAWINGS

FIG. 1 shows a schematic, not to scale, view of an overall broad conception of a photolithography system according to an aspect of the disclosed subject matter.

FIG. 2 shows a schematic, not to scale, view of an overall broad conception of an illumination system according to an aspect of the disclosed subject matter.

FIG. 3 is a diagrammatic cross section, not to scale, of a discharge chamber for an excimer laser according to aspects of the disclosed subject matter.

FIGS. 4A-4C are conceptual illustrations of a side view of a laser discharge chamber use to aid explanation of certain principles relating to the disclosed subject matter.

FIGS. 5A-5F are cross sectional views of a discharge surface of a laser electrode according to aspects of the disclosed subject matter.

FIGS. 6A-6E are plan views of a portion of an engineered discharge surface according to aspects of embodiments of the disclosed subject matter.

FIGS. 7A and 7B are plan views of a portion of an engineered discharge surface according to aspects of embodiments of the disclosed subject matter.

FIGS. 8A-8D are plan views of a portion of an engineered discharge surface according to aspects of embodiments of the disclosed subject matter.

FIG. 9 is a plan view of a portion of an engineered discharge surface according to aspects of embodiments of the disclosed subject matter.

FIGS. 10A-10F are plan views of a portion of an engineered discharge surface according to aspects of embodiments of the disclosed subject matter

FIG. 11 is a perspective view of a portion of an engineered discharge surface according to aspects of embodiments of the disclosed subject matter.

Further features and advantages of the disclosed subject matter, as well as the structure and operation of various embodiments of the disclosed subject matter, are described in detail below with reference to the accompanying drawings. It is noted that the applicability of the disclosed subject matter is not limited to the specific embodiments described herein. Such embodiments are presented herein for illustrative purposes only. Additional embodiments will be apparent to persons skilled in the relevant art based on the teachings contained herein.

### DETAILED DESCRIPTION

Various embodiments are now described with reference to the drawings, wherein like reference numerals are used to refer to like elements throughout. In the following description, for purposes of explanation, numerous specific details are set forth in order to promote a thorough understanding of one or more embodiments. It may be evident in some or all instances, however, that any embodiment described below can be practiced without adopting the specific design details described below. In other instances, well-known structures and devices are shown in block diagram form in order to facilitate description of one or more embodiments. This summary is not an extensive overview of all contemplated embodiments and is not intended to identify key or critical elements of all embodiments nor delineate the scope of any or all embodiments.

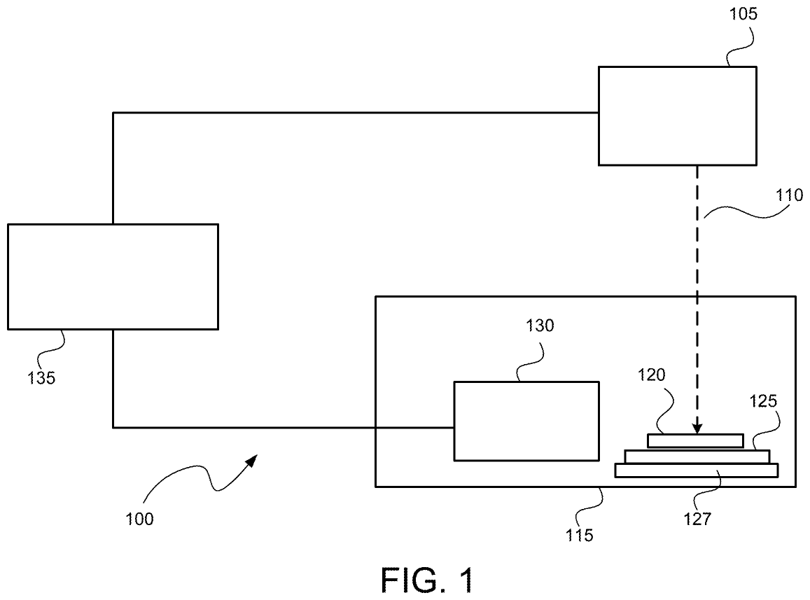

FIG. 1 is a functional block diagram of a photolithography system 100 that includes an illumination system 105. As described more fully below, the illumination system 105 includes a light source that produces a pulsed light beam 110 and directs it to a photolithography exposure apparatus or scanner 115 that patterns microelectronic features on a wafer 120. The wafer 120 is placed on a wafer table 125 constructed to hold wafer 120 and connected to a positioner 127 configured to accurately position the wafer 120 in accordance with certain parameters.

The pulsed light beam 110 has a wavelength in the deep ultraviolet (DUV) portion of the spectrum, for example, with wavelengths of 248 nanometers (nm) or 193 nm. The minimum size of the microelectronic features that can be patterned on the wafer 120 depends on the wavelength of the pulsed light beam 110, with a lower wavelength permitting the creation of features having a smaller minimum feature size. When the wavelength of the pulsed light beam 110 is 248 nm or 193 nm, the minimum size of the microelectronic features can be, for example, 50 nm or less. The bandwidth of the pulsed light beam 110 can be the actual, instantaneous bandwidth of its optical spectrum (or emission spectrum), which contains information on how the optical energy of the pulsed light beam 110 is distributed over different wavelengths.

The scanner 115 can include, among other features, a lithography controller 130, air conditioning devices (not shown), and power supplies (not shown) for the various electrical components. The lithography controller 130 controls how layers are printed on the wafer 120. The lithography controller 130 includes a memory that stores information such as process recipes that determine the length of the exposure on the wafer 120 based on, for example, the mask used, as well as other factors that affect the exposure. During lithography, a plurality of pulses of the light beam 110 illuminates the same area of the wafer 120 to together constitute an illumination dose.

The photolithography system 100 also preferably includes a control system 135. In general, the control system 135 includes one or more of digital electronic circuitry, computer hardware, firmware, and software. The control system 135 also includes memory which can be read-only memory and/or random access memory. Storage devices suitable for tangibly embodying computer program instructions and data include all forms of non-volatile memory, including, by way of example, semiconductor memory devices, such as EPROM, EEPROM, and flash memory devices; magnetic disks such as internal hard disks and removable disks; magneto-optical disks; and CD-ROM disks.

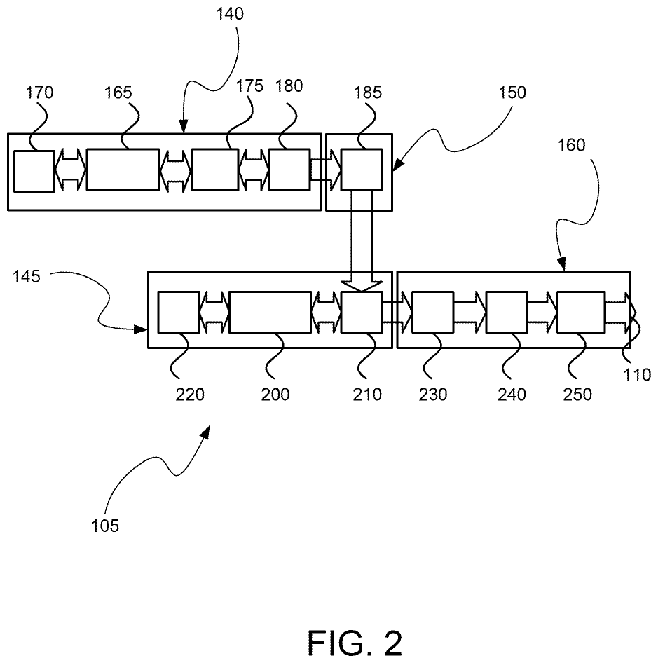

FIG. 2 shows illustratively and in block diagram a gas discharge laser system 105 according to an embodiment of certain aspects of the disclosed subject matter. The gas discharge laser system may include, e.g., a solid state or gas discharge seed laser system 140, an amplification stage, e.g., a power ring amplifier (“PRA”) stage 145, relay optics 150, and laser system output subsystem 160.

The seed system 140 may include, e.g., a master oscillator (“MO”) chamber 165. The seed laser system 140 may also include a master oscillator output coupler (“MO OC”) 175, which may comprise a partially reflective mirror, forming with a reflective grating (not shown) in a line narrowing module (“LNM”) 170, an oscillator cavity in which the seed laser 140 oscillates to form the seed laser output pulse, i.e., forming a master oscillator (“MO”). The system may also include a line-center analysis module (“LAM”) 180. The LAM 180 may include an etalon spectrometer for fine wavelength measurement and a coarser resolution grating spectrometer. A MO wavefront engineering box (“WEB”) 185 may serve to redirect the output of the MO seed laser system 140 toward the amplification stage 145, and may include, e.g., beam expansion with, e.g., a multi prism beam expander (not shown) and coherence busting, e.g., in the form of an optical delay path (not shown).

The amplification stage 145 may include, e.g., a PRA lasing chamber 200, which may also be an oscillator, e.g., formed by seed beam injection and output coupling optics (not shown) that may be incorporated into a PRA WEB 210 and may be redirected back through the gain medium in the chamber 200 by a beam reverser 220. The PRA WEB 210 may incorporate a partially reflective input/output coupler (not shown) and a maximally reflective mirror for the nominal operating wavelength (e.g., at around 193 nm for an ArF system) and one or more prisms.

A bandwidth analysis module (“BAM”) 230 at the output of the amplification stage 145 may receive the output laser light beam of pulses from the amplification stage and pick off a portion of the light beam for metrology purposes, e.g., to measure the output bandwidth and pulse energy. The laser output light beam of pulses then passes through an optical pulse stretcher (“OPuS”) 240 and an output combined autoshutter metrology module (“CASMM”) 250, which may also be the location of a pulse energy meter.

The PRA lasing chamber 200 and the MO 165 are configured as chambers in which electrical discharges between electrodes may cause lasing gas discharges in a lasing gas to create an inverted population of high energy molecules, including, e.g., ArF*, KrF*, and/or XeF* dimers, to produce relatively broad band radiation that may be line narrowed to a relatively very narrow bandwidth and center wavelength selected in the LNM 170, as is known in the art. The above describes a two chamber system. It is also possible that the system will include only a single laser chamber or three or more chambers.

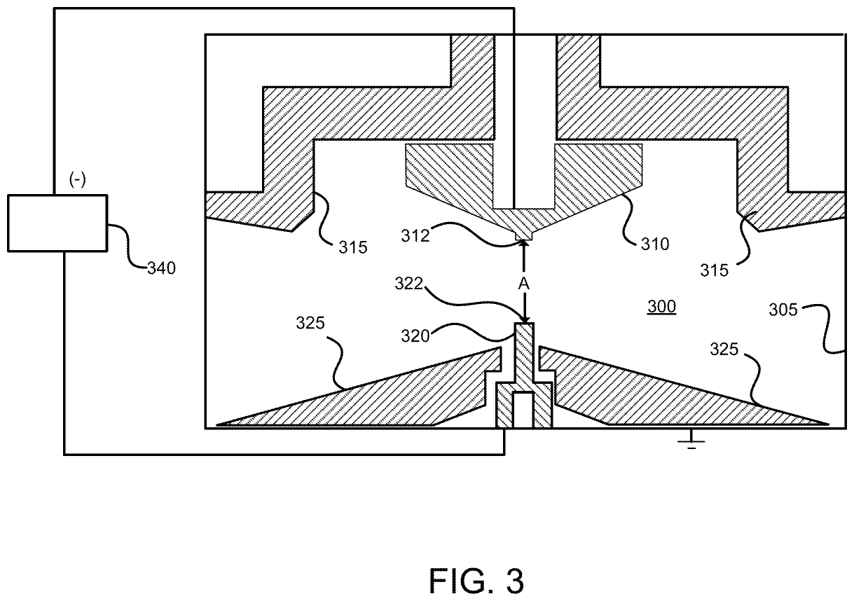

FIG. 3 is a highly stylized cross-sectional diagram of an example of a discharge chamber 300. The chamber 300 includes an upper electrode 310 that may act as a cathode and a lower electrode 320 that may act as an anode. These electrodes extend into and out of the plane of the figure in a lengthwise direction. The electrodes are longer in this lengthwise direction than they are wide in the transverse dimension shown in the figure. One or both of the lower electrode 320 and the upper electrode 310 may be entirely contained in the pressure envelope of chamber 300 defined by the chamber wall 305 or one of the electrodes may not be so contained. The electrode 310 has a discharge surface 312 and the electrode 320 has a discharge surface 322. Lasing gas discharges occur between these two electrode discharge surfaces across a gap A.

Also shown in FIG. 3 are an upper insulator 315 and a lower insulator 325. The lower electrode 320 is electrically connected to the wall 305 of the chamber 300. For safety reasons it is desirable to maintain the chamber wall 300 and so the lower electrode 320 at ground potential. In the embodiment shown in FIG. 3, the upper electrode 310 is driven by a voltage supply 340 with pulses that are negative with respect to the lower electrode 320. It is possible, however, to have configurations in which this polarity is reversed.

As mentioned, also shown in FIG. 3 is the voltage supply 340 which establishes a voltage gradient across the cathode 310 and the anode 320. While the notation (−) is shown for the polarity of the output of the voltage supply 340 it will be understood that this is a relative rather than absolute polarity, that is, relative to the polarity of the lower electrode 320. The upper electrode (cathode 310) is charged to a large negative voltage during pulsing. The large negative voltage may be ˜20 kV in one embodiment, but other voltages are used in other embodiments.

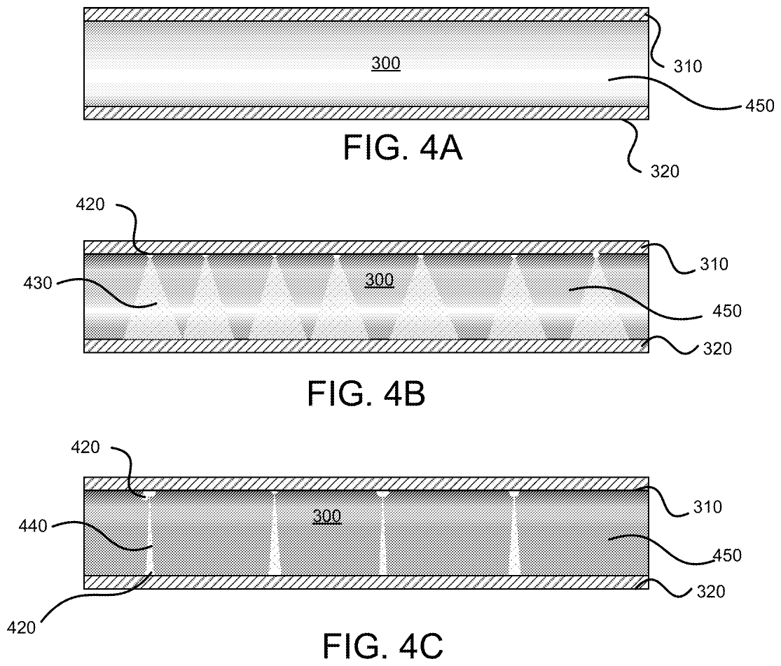

In operation, the application of a voltage across the electrodes 310, 320 causes a discharge 450 to occur in the laser chamber 300 between the discharge surface 312 and the discharge surface 322. This is shown in FIG. 4A which is a side view of part of the length of the laser chamber 300. Ideally, this discharge 450 is relatively uniform in space. It can occur, however, that the overall discharge in the laser chamber 300 can start to become nonuniform and exhibit areas of higher discharge density to the point of becoming striated with streaks or streamers of concentrated discharge forming between the discharge surface 312 and the discharge surface 322. The onset of this process is shown in FIG. 4B. In FIG. 4B, discharge arcs 420 have begun to form on the cathode 310. This results in areas of concentrated discharge 430 as shown in FIG. 4B. These areas of concentrated discharge 430 steal energy from the uniform discharge 450. As shown in FIG. 4C, this process can continue until the areas of higher discharge density effectively become streamers 440 and discharge arcs 420 begin to appear on the anode 320. It will be noted that not only does the overall discharge become increasingly nonuniform but that the number of concentrated discharges 420 also decreases.

The formation of areas of nonuniform discharge in the chamber can result in undesirable effects. Most pronounced, these areas of higher discharge density can in effect rob energy from the radiation producing plasma in the chamber 300 and so worsen the efficiency of the laser. In other words, once these areas of higher discharge density form, the laser requires more voltage across the electrodes 310, 320 to produce the same amount of laser radiation energy in the chamber 300. If the electrode voltage is kept constant, then the chamber 300 will produce less laser energy.

It is therefore desirable to identify ways to mitigate this deterioration of the laser chamber discharge process. In accordance with an aspect of an embodiment, such mitigation is implemented by engineering the discharge surface of a least one of the electrodes by fabricating a distribution of structures on the discharge surface which establish engineered distribution discharge concentration sites. These engineered distribution discharge concentration sites are also referred to as engineered discharge nucleation sites herein. These engineered distribution discharge concentration sites are features which have edges creating a higher local electric field strength which make the edges more likely sites for discharge nucleation. Here and elsewhere, the term “engineered” is used to connote that the structures are deliberately provided or arranged rather than arising naturally or spontaneously as a byproduct of a machining process used to make the electrode or of plasma effects. The surfaces on which the structures appear will be referred to as engineered surfaces. The term “distribution” and its cognates (e.g., distribute, distributed) are intended to connote that the structures so described are arranged so that concentrated discharges are spaced away from one another and will display less of a tendency to cluster or coalesce into a smaller number of larger discharge streamers or arcs. The distribution of engineered nucleation sites for the concentrated discharge is designed to mitigate the tendency of the discharge to concentrate to fewer sites/hot spots.

In other words, rather than permitting the discharge density striations to occur as they would spontaneously, a process in which the striations become increasingly concentrated and the number of concentration sites decreases, a distribution of nucleation sites is proactively/intentionally/artificially provided to affect where these concentrated discharges are most likely to occur and their number and to inhibit coalescence. The nucleation sites are engineered to have features with a small radius of curvature tending to increase the strength of the electrical field in their vicinity. Therefore, there will be a tendency for the discharges to preferentially initiate at these distributed features rather than randomly and in clusters.

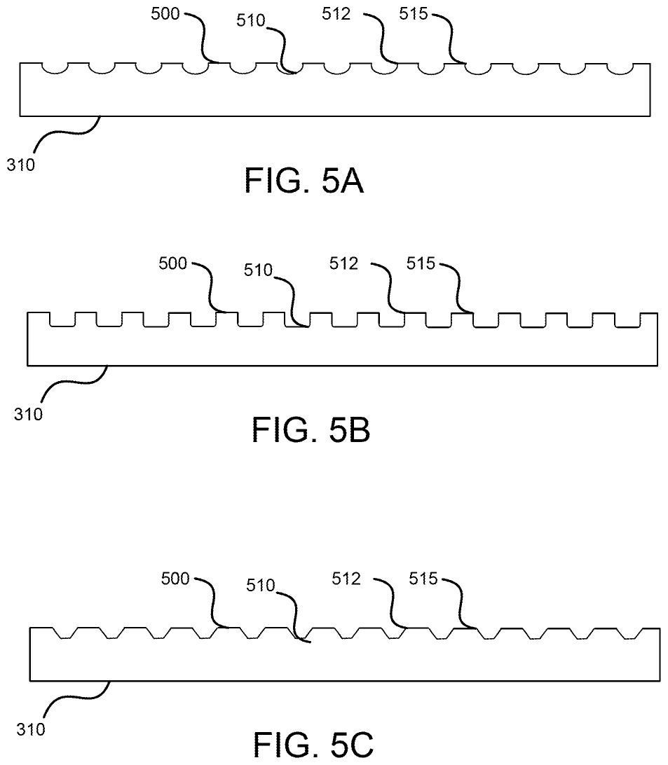

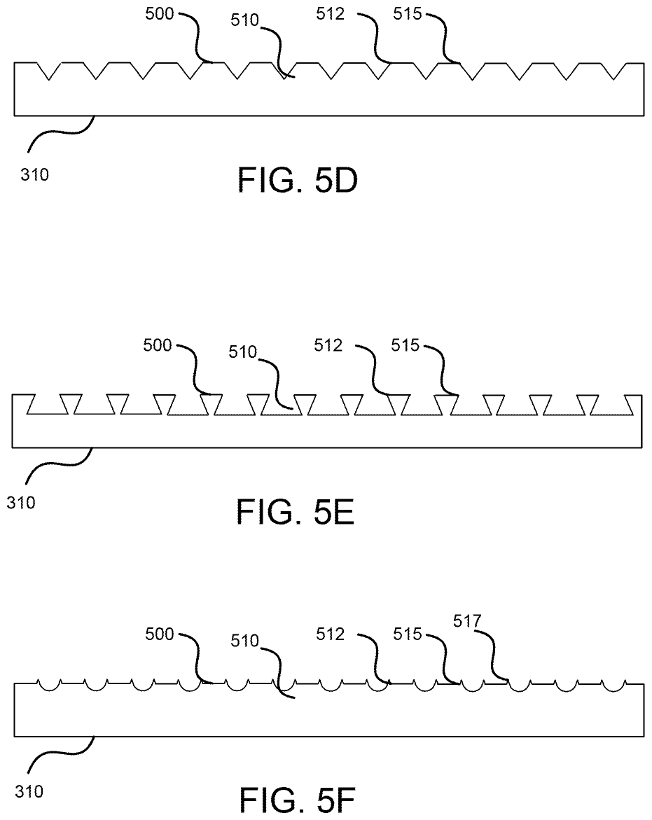

Thus, as shown in the cutaway side view of FIG. 5A, the surface of one of the electrodes is structured with crests and troughs with the corners (edges) of the crests having a small radius of curvature and being locations at which a concentrated discharge is thus more likely to occur. In the example of FIG. 5A and the discussion which follows, the electrode is the cathode 310. It will be understood, however, that the surface engineering described herein could be applied to either or both electrodes. More particularly, the discharge surface 312 of the cathode 310, that is, the surface which will confront the discharge surface 322 of the anode 320 across the gap A in which the plasma is formed as shown in FIG. 3, includes crests 500 and troughs 510 with the corners/edges of the crest 500, that is, the corners 512 and 515. These define regions in which discharges between the cathode 310 and the anode 320, are more likely to concentrate and form streamers (or concentrated discharge) due to stronger localized electric fields at these sharp corners. It is believed that concentrated discharges will form preferentially at these discharge attractors analogously to the manner in which lightning preferentially strikes lightning rods.

The troughs 510 have a curved cross section in the embodiment of FIG. 5A. It will be apparent to one of ordinary skill in the art, however, that the troughs 510 may have cross sectional shapes other than those depicted in FIG. 5A. For example, as shown in FIG. 5B, the troughs 510 may have a square cross sectional profile. As shown in FIG. 5C, the troughs 510 may have an open (base up) trapezoidal cross section. As shown in FIG. 5D, the troughs 510 may have a triangular cross section. As shown in FIG. 5E, the troughs 510 may have a narrowed (base down) trapezoidal cross section with the longer parallel side of the trapezoid forming the base of the trough. As shown in FIG. 5F, the troughs 510 may have a curved cross section with projections 517 jutting past the adjacent surface. It will be apparent that many other configurations are possible.

These surface textures or topographies can be created using, for example, drilling or indentation techniques. The overall effect of engineering these surface topographies is to deliberately introduce structures that will attract discharges that have less of a tendency to be clustered or grouped.

These surface topographies can also be created by filing/scratching the electrode surface using hard tips or tools. Such a process can be expected to create troughs, for example, having cross sectional configurations such as those shown in FIGS. 5D and 5F. Regarding the configuration of FIG. 5F, the projections 517 at the edges of the trough 510 are intentionally created in the roughening process, in which the electrode material can be “raised” by the impingement of a hard tool tip.

All of the figures show only a small portion of the discharge surface of the electrode. Also, the relative size of the electrode and the features is modified to promote clear illustration. In practice, the dimensions of the features will be smaller than the dimensions of the electrode discharge surface so that many such features appear on the discharge surface. As an example, an electrode discharge surface may be on the order of 0.5 m long and 0.005 m (5 mm) wide for a total surface area of about 2.5×10⁻³ m². The size of a cell (repeating unit) of the structured distribution, the width of the structure plus the spacing to adjacent cells, may be on the order of 500 μm in both directions for an area of 2.5×10⁻⁷ m². The total number of cells in this example will then be roughly on the order of 104, so that it is possible there will be this many cells or more on the discharge surface. For some implementations the number of cells will generally be in a range of about 103 to about 106.

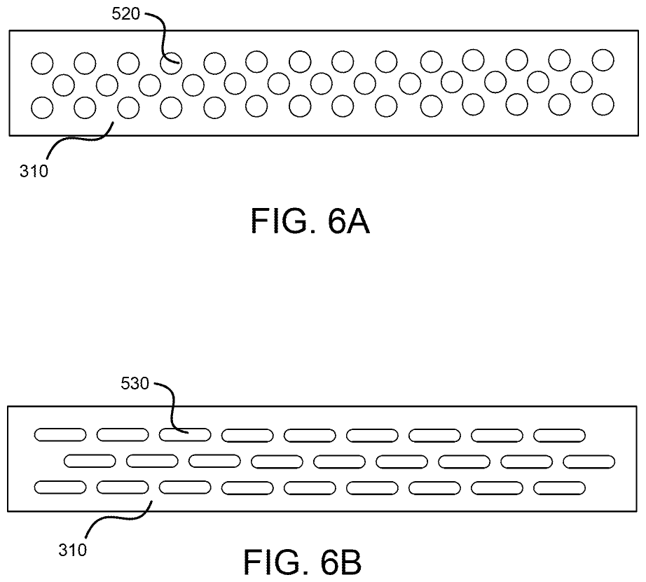

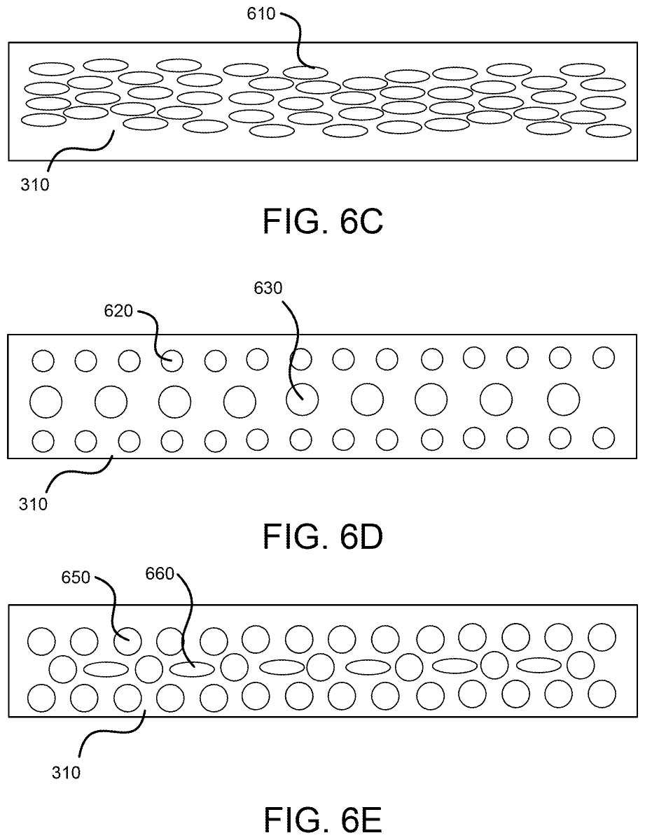

FIG. 6A shows one possible layout for the engineered structures provided on the surface of the cathode 310 in accordance with an aspect of an embodiment. This view, and the views which follow, are looking at the discharge surface 312 of the cathode 310 from the perspective of the discharge surface 322 of the anode 320, that is, looking upward in FIG. 3 and FIGS. 4A-4C. In the embodiment of FIG. 6A the structures are implemented as a periodic arrangement of circles 520. It will be apparent to one of ordinary skill in the art, however, that other shapes may be used. For example, in the embodiment of FIG. 6B, the structured surface is implemented as a periodic arrangement of oblongs 530.

In the embodiments just described, the arrangements are periodic. It will be apparent to one of ordinary skill in the art, however, that it is not strictly necessary that the arrangement be periodic and that the distribution of the surface features can be aperiodic or random. Thus, in the embodiment of FIG. 6C, the ovals 610 are arranged essentially randomly.

As shown in FIG. 6D, in accordance with an aspect of an embodiment, if a single shape is used, the sizes of the shape may be varied. Thus, in the embodiment of FIG. 6D, there is an arrangement of smaller circles 620 interspersed with an arrangement of larger circles 630. Also, as shown in FIG. 6E, in accordance with an aspect of an embodiment, not all the shapes in the arrangement need be the same and the arrangement may be made up of a mixture of shapes. Thus, in the embodiment of FIG. 6E, there is an arrangement of smaller circles 650 interspersed with an arrangement of ovals 660.

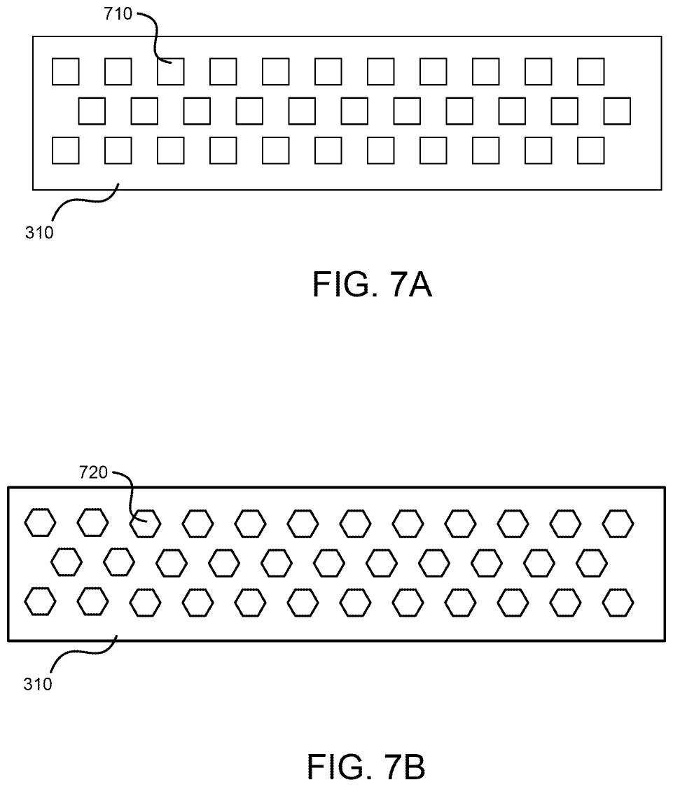

The above examples of embodiments are made up of shapes generally having rounded contours but it will be appreciated by one of ordinary skill in the art that other shapes may be used. For example, in the embodiment of FIG. 7A, the engineered structured surface is made up of an arrangement of square elements 710. Similarly, in the embodiment of FIG. 7B, the engineered structured surface is made up of an arrangement of hexagonal elements 720.

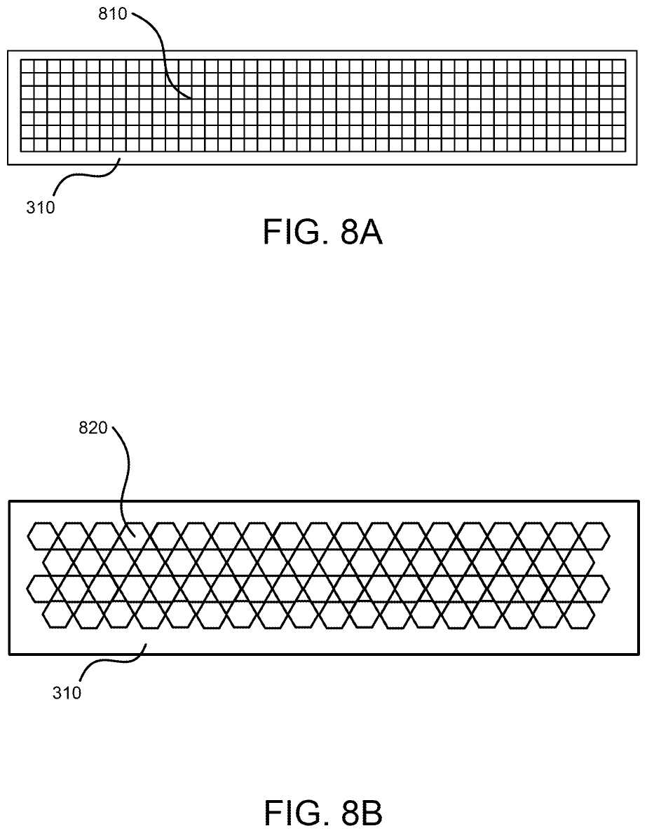

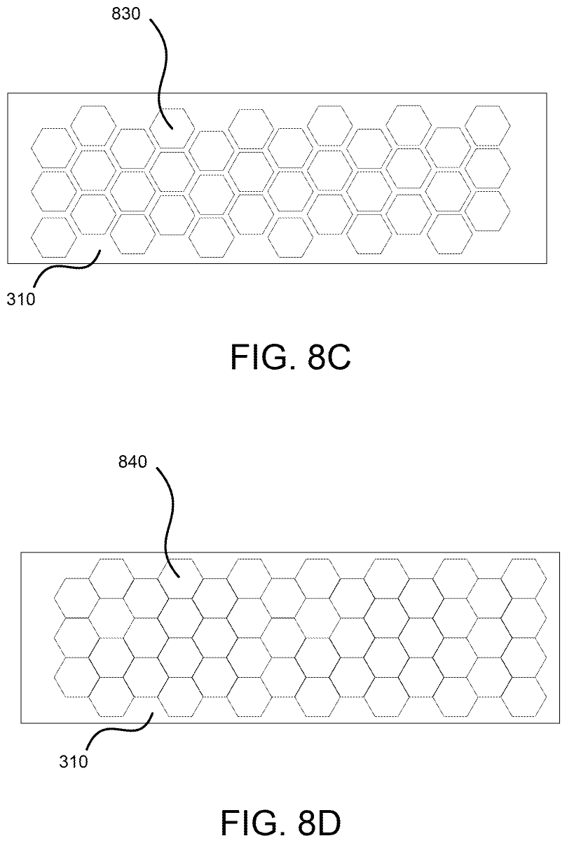

The above examples of embodiments use arrangements of discrete shapes. The distribution of structures giving rise to discharge-promoting sites, however, may also be implemented as a grid. Thus, in the embodiment of FIG. 8A, the engineered structured surface is implemented as a square grid 810. In the embodiment of FIG. 8B the engineered structured surface is implemented as a grid of hexagonal shapes 820. In the embodiment of FIG. 8C, the engineered structured surface is implemented as a grid of discrete hexagons 830. In the embodiment of FIG. 8D the engineered structured surface is implemented as a grid of abutting hexagons 840 in a honeycomb arrangement.

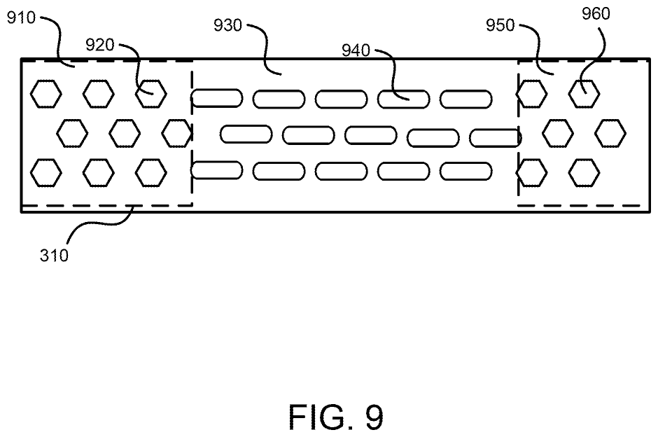

It will also be apparent to one of ordinary skill in the art that the engineered structured surface may be made up of multiple regions with each region having a different cell structure or configuration. Thus, as shown in FIG. 9, the engineered structured surface is made up of a first region 910 comprised of an arrangement of hexagonal cells 920, a second region 930 comprised of an arrangement of oblong elements 940, and a third region 950 made up again of an arrangement of hexagonal elements 960.

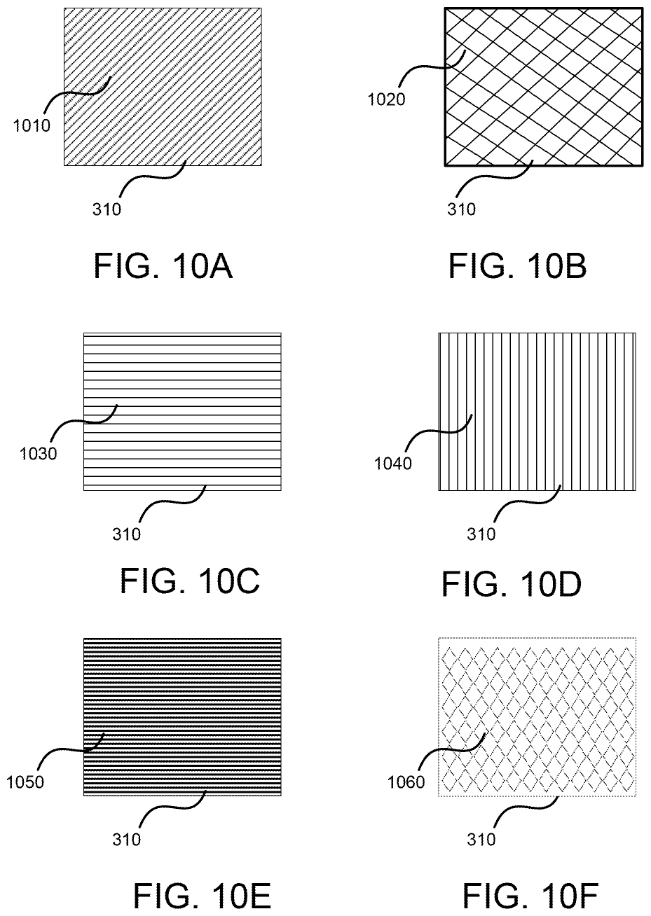

As mentioned, the surface topography may be created by filing or etching the surface of the electrode to form tracks or channels. The filing or etching may be random or may be in a pattern. FIGS. 10A-10F show various patterns which may be created. Thus, FIG. 10A shows a diagonal pattern for the surface of the electrode 310 having tracks 1010. The tracks 1010 may be parallel and evenly spaced as shown, or may be more randomly distributed if, for example, they are formed by filing or scratching the surface of the electrode 310. FIG. 10B shows a cross hatched pattern with tracks 1020. Again, and for all of these patterns, the tracks 1020 may be periodic and evenly spaced as shown, or may be more randomly distributed if, for example, they are formed by filing or scratching the surface of the electrode 310. FIG. 10C shows a pattern of tracks 1030 running parallel to the length of the surface of the electrode 310. FIG. 10D shows a pattern of tracks 1040 running transverse to the length of the surface of the electrode 310. FIG. 10E shows a dense pattern of tracks 1050 running parallel to length of the surface of the electrode 310. FIG. 10F shows a dense diamond pattern of crisscrossing tracks 1060.

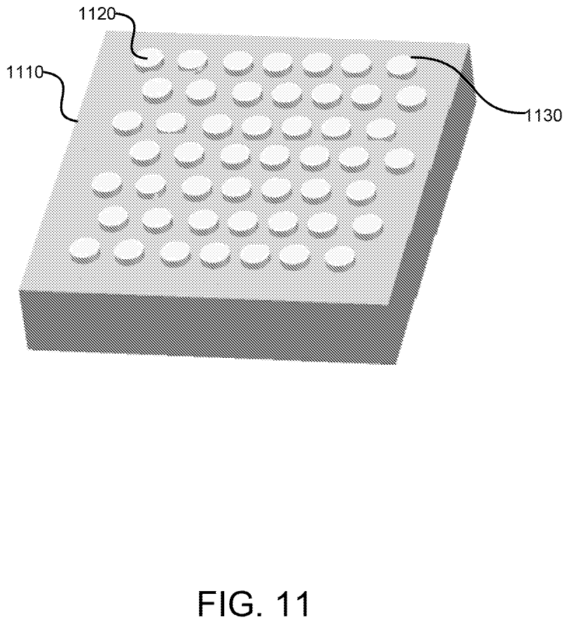

The foregoing describes engineered discharge nucleation sites which are parts of indentations in the discharge surface of the electrode. The patterns of indentations may also be viewed as patterns of protrusions. It will be apparent to one of ordinary skill in the art that the engineered discharge nucleation sites may also or alternatively be part of raised portions of the electrode discharge surface. Thus, as shown in FIG. 11, a portion of electrode surface 1110 is provided with raised portions 1120 having edges 1130. In FIG. 11, the raised portions are cylindrical but it will be understood that other shapes may be used and that at any of the variations described above may be implemented as raised portions rather than as indentations. These raised portions may be formed, for example, by using a masked plasma etch process.

It will also be apparent that the pitch or spacing of the elements in the longitudinal direction, that is, along the length of the electrode discharge surface, need not be the same as their pitch in the transverse direction.

The surface structure may be engineered on the discharge surface of an electrode using any one of a number of possible methods. For example, the surface structure could be engineered by using an ex-situ pretreatment with laser drilling. As an alternative, the surface structure could be engineered using an ex-situ pretreatment with a chemical etch similar to what is used to pattern printed circuit boards. As another alternative, the surface structure can be engineered using an ex-situ pretreatment using dry plasma etch. Alternatively, the surface structure could be engineered using an ex-situ pretreatment involving mechanical drilling, filing, scratching, hatching, indentation, or some combination of these. The surface structure may also be engineered in-situ using a pretreatment implemented using a plasma chamber plasma discharge firing. Of course, these are just some alternatives, and it will be apparent to one of ordinary skill in the art that other techniques and methods may be used.

It will be apparent to one of ordinary skill in the art that the dimensions for the surface features and the arrangements can be selected from a wide range of possible values. For example, the arrangement of circles 520 of the arrangement of FIG. 6A may have a center-to-center spacing in the range of about 10 μm to about 1000 μm and the circles may have a radius in this same range depending on what center-to-center spacing is selected. As a specific example, the arrangement of circles 520 of the arrangement of FIG. 6A may have a center-to-center spacing of about 550 μm and the circles may have a radius of about 200 μm. The depths of the circles may be in the range of about 10 μm to about 1000 μm. Such an arrangement of circles can be created using, for example, laser drilling or mechanical indentation. The area coverage of the features for these dimensions is around 48%.

As another example, the arrangement of oblongs 530 of the arrangement of FIG. 6B may have a lateral center-to-center spacing of about 1400 μm, a transverse center-to-center spacing of about 450, with the individual oblongs 530 having a height of about 300 μm and a length of about 1100 μm. The depths of the oblongs may be in the range of about 20 μm to about 200 μm. Such an arrangement of oblongs can be created using, for example, laser drilling. The area coverage of the features for these dimensions is around 48%.

The engineered features with their edges essentially add a controlled roughness to the surface of the electrode. This roughness is added in such a way as to create a large number of features with those features for the most part being spaced to as to avoid coalescing of streamers. Assuming a relative uniform spacing of features then surface roughness, e.g., Ra, gives a measure of expected surface effectiveness. For some embodiments, the surface roughness Ra may be greater than about 30 μm.

In general the periphery per unit area for the engineered structured surface, which is the length of the periphery of a feature divided by the surface area of a cell containing the feature, provides a measure of the amount of potential nucleation sites present. For example, for a periodic arrangement of cells if the feature in each cell is a circle with diameter D then the periphery of the feature is the circumference of the circle or πD. If the center-to-center spacing between circles is s then the cell size is s and the area of a cell is s². Then periphery of the feature divided by the surface area of the cell is πD/s². In general it is preferred for some applications that the periphery per unit area is in a range of 1 mm⁻¹ to about 20 mm⁻¹. The periphery per unit area for the arrangement of FIG. 6A is about 4.2 mm⁻¹. The periphery per unit area for the arrangement of FIG. 6B is about 4.4 mm⁻¹. The above description includes examples of multiple embodiments. It is, of course, not

possible to describe every conceivable combination of components or methodologies for purposes of describing the aforementioned embodiments, but one of ordinary skill in the art may recognize that many further combinations and permutations of various embodiments are possible. Accordingly, the described embodiments are intended to embrace all such alterations, modifications, and variations that fall within the spirit and scope of the appended claims. Furthermore, to the extent that the term “includes” is used in either the detailed description or the claims, such term is intended to be inclusive in a manner similar to the term “comprising” as “comprising” is construed when employed as a transitional word in a claim. Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

The implementations and/or embodiments can be further described using the following clauses:

1. An electrode for a laser discharge chamber, the electrode comprising an engineered discharge surface, the engineered discharge surface comprising a distribution of a plurality of engineered discharge nucleation sites.

2. The electrode of clause 1 wherein the engineered discharge surface comprises a plurality of engineered indentations each having an edge and wherein each of the engineered nucleation sites comprises at least a portion of the edge of an associated one of the engineered indentations.

3. The electrode of clause 1 wherein the engineered discharge surface comprises a plurality of engineered protrusions and wherein each of the engineered nucleation sites comprises at least a portion of an edge of an associated one of the engineered protrusions.

4. The electrode of clause 1 wherein the engineered discharge surface comprises a plurality of engineered tracks each having an edge and wherein each of the engineered nucleation sites comprises at least a portion of the edge of each of the engineered tracks.

5. The electrode of clause 2 wherein the engineered indentations have a depth in the range of about 10 μm to about 1000 μm.

6. The electrode of clause 2 wherein the engineered indentations are formed by laser drilling.

7. The electrode of clause 2 wherein the engineered indentations are formed by chemical etching.

8. The electrode of clause 2 wherein the engineered indentations are formed by plasma etching.

9. The electrode of clause 2 wherein the plurality of engineered indentations are formed by mechanical drilling.

10. The electrode of clause 2 wherein the plurality of engineered indentations are formed by mechanical indentation.

11. The electrode of clause 1 wherein a first subset of the engineered discharge nucleation sites have a first shape and wherein a second subset of the engineered discharge nucleation sites have a second shape different from the first subset shape.

12. The electrode of clause 2 wherein the engineered indentations are circular engineered indentations.

13. The electrode of clause 12 wherein the circular engineered indentations have a radius having a same length.

14. The electrode of clause 12 wherein a first subset of the circular engineered indentations have a radius having a first subset length and wherein a second subset of the circular engineered indentations have a radius having a second subset length different from the first subset length.

15. The electrode of clause 12 wherein the circular engineered indentations have a radius in the range of about 10 μm to about 1000 μm.

16. The electrode of clause 12 wherein the circular engineered indentations are arranged in a periodic arrangement with a center-to-center spacing in the range of about 10 μm to about 1000 μm.

17. The electrode of clause 1 wherein the engineered discharge surface has a periphery per unit area in a range of 1 mm⁻¹ to about 20 mm⁻¹.

18. The electrode of clause 2 wherein the engineered indentations are oblong engineered indentations.

19. The electrode of clause 18 wherein the discharge surface has a lengthwise dimension and a shorter widthwise dimension and wherein the oblong engineered indentations are arranged in a periodic arrangement with a spacing in the lengthwise dimension in the range of about 10 μm to about 1000 μm.

20. The electrode of clause 1 wherein the distribution of a plurality of engineered discharge nucleation sites comprises an arrangement of engineered discharge nucleation sites.

21. The electrode of clause 20 wherein the arrangement is periodic.

22. The electrode of clause 20 wherein the arrangement is random.

23. The electrode of clause 1 wherein the discharge surface has a lengthwise dimension and a shorter widthwise dimension and wherein the engineered discharge nucleation sites have a first spacing in the lengthwise dimension and a second spacing in the widthwise dimension.

24. The electrode of clause 23 wherein the first spacing is the same as the second spacing.

25. The electrode of clause 23 wherein the first spacing is different from the second spacing.

26. The electrode of clause 1 wherein the engineered discharge nucleation sites comprise a plurality of substantially parallel ridges with adjacent ridges defining an associated trough therebetween.

27. The electrode of clause 26 wherein the trough has an arcuate cross section.

28. The electrode of clause 26 wherein the trough has a substantially semicircular cross section.

29. The electrode of clause 26 wherein the trough has a substantially rectangular cross section.

30. The electrode of clause 26 wherein the trough has a substantially trapezoidal cross section.

31. The electrode of clause 26 wherein the trough has a substantially V-shaped cross section.

32. The electrode of clause 26 wherein the trough has an arcuate cross section with a lateral projection rising above an adjacent portion of an adjacent ridge with which the trough is associated.

33. A system for generating laser radiation comprising:
a discharge chamber;
a first electrode positioned at least partially within the discharge chamber; and
a second electrode positioned at least partially within the discharge chamber, the first electrode having a first discharge surface and the second electrode having a second discharge surface, the first discharge surface and the second discharge surface being arranged to confront one another across a gap
wherein at least one of the first discharge surface and the second discharge surface comprises a distribution of a plurality of engineered discharge nucleation sites.

34. The system of clause 33 wherein the first electrode is connected to function as a cathode and wherein the first discharge surface comprises the distribution of a plurality of engineered discharge nucleation sites 35. The system of clause 33 wherein the first discharge surface comprises a plurality of engineered indentations each having an edge and wherein each of the engineered nucleation sites comprises at least a portion of the edge of an associated one of the engineered indentations.

36. The system of clause 35 wherein the engineered indentations have a depth in the range of about 10 μm to about 1000 μm.

37. The system of clause 35 wherein the engineered indentations are formed by laser drilling.

38. The system of clause 35 wherein the engineered indentations are formed by chemical etching.

39. The system of clause 35 wherein the engineered indentations are formed by plasma etching.

40. The system of clause 35 wherein the engineered indentations are formed by mechanical drilling.

41. The system of clause 35 wherein the engineered indentations are formed by mechanical indentation.

42. A method of making a discharge electrode for a laser discharge chamber, the method comprising:
providing an electrode having a discharge surface; and
creating a distribution of a plurality of engineered discharge nucleation sites on the discharge surface.

43. The method of clause 42 wherein creating a distribution of a plurality of engineered discharge nucleation sites on the discharge surface comprises laser drilling the engineered discharge nucleation sites.

44. The method of clause 42 wherein creating a distribution of a plurality of engineered discharge nucleation sites on the discharge surface comprises chemical etching.

45. The method of clause 42 wherein creating a distribution of a plurality of engineered discharge nucleation sites on the discharge surface comprises plasma etching the engineered discharge nucleation sites.

46. The method of clause 42 wherein creating a distribution of a plurality of engineered discharge nucleation sites on the discharge surface comprises mechanically drilling the engineered discharge nucleation sites.

47. The method of clause 42 wherein creating a distribution of a plurality of engineered discharge nucleation sites on the discharge surface comprises mechanically indenting the engineered discharge nucleation sites.

The breadth and scope of the embodiments should not be limited by any of the above-described embodiments which are provided by way of example, but should be defined only in accordance with the following claims and their equivalents.

1. An electrode for a laser discharge chamber, the electrode comprising an engineered discharge surface, the engineered discharge surface comprising a distribution of a plurality of engineered discharge nucleation sites.

2. The electrode of claim 1 wherein the engineered discharge surface comprises a plurality of engineered indentations each having an edge and wherein each of the engineered nucleation sites comprises at least a portion of the edge of an associated one of the engineered indentations.

3. The electrode of claim 1 wherein the engineered discharge surface comprises a plurality of engineered protrusions and wherein each of the engineered nucleation sites comprises at least a portion of an edge of an associated one of the engineered protrusions.

4. The electrode of claim 1 wherein the engineered discharge surface comprises a plurality of engineered tracks each having an edge and wherein each of the engineered nucleation sites comprises at least a portion of the edge of each of the engineered tracks.

5. The electrode of claim 2 wherein the engineered indentations have a depth in the range of about 10 μm to about 1000 μm.

6.-10. canceled

11. The electrode of claim 1 wherein a first subset of the engineered discharge nucleation sites have a first shape and wherein a second subset of the engineered discharge nucleation sites have a second shape different from the first subset shape.

12.-13. canceled

14. The electrode of claim 2 wherein the engineered indentations are circular engineered indentations, and wherein a first subset of the circular engineered indentations have a radius having a first subset length and wherein a second subset of the circular engineered indentations have a radius having a second subset length different from the first subset length.

15. The electrode of claim 2 wherein the engineered indentations are circular engineered indentations, and wherein the circular engineered indentations have a radius in the range of about 10 μm to about 1000 μm.

16. The electrode of claim 2 wherein the engineered indentations are circular engineered indentations, and wherein the circular engineered indentations are arranged in a periodic arrangement with a center-to-center spacing in the range of about 10 μm to about 1000 μm.

17. The electrode of claim 1 wherein the engineered discharge surface has a periphery per unit area in a range of 1 mm⁻¹ to about 20 mm⁻¹.

18. canceled

19. The electrode of claim 2 wherein the engineered indentations are oblong engineered indentations, and wherein the discharge surface has a lengthwise dimension and a shorter widthwise dimension and wherein the oblong engineered indentations are arranged in a periodic arrangement with a spacing in the lengthwise dimension in the range of about 10 μm to about 1000 μm.

20. canceled

21. The electrode of claim 1 wherein the distribution of a plurality of engineered discharge nucleation sites comprises an arrangement of engineered discharge nucleation sites, and wherein the arrangement is periodic.

22. The electrode of claim 1 wherein the distribution of a plurality of engineered discharge nucleation sites comprises an arrangement of engineered discharge nucleation sites, and wherein the arrangement is random.

23. The electrode of claim 1 wherein the discharge surface has a lengthwise dimension and a shorter widthwise dimension and wherein the engineered discharge nucleation sites have a first spacing in the lengthwise dimension and a second spacing in the widthwise dimension.

24. The electrode of claim 23 wherein the first spacing is the same as the second spacing.

25. The electrode of claim 23 wherein the first spacing is different from the second spacing.

26. The electrode of claim 1 wherein the engineered discharge nucleation sites comprise a plurality of substantially parallel ridges with adjacent ridges defining an associated trough therebetween.

27. The electrode of claim 26 wherein the trough has an arcuate cross section, a substantially semicircular cross section, a substantially rectangular cross section, a substantially trapezoidal cross section, or a substantially V-shaped cross section.

28.-31. canceled

32. The electrode of claim 26 wherein the trough has an arcuate cross section with a lateral projection rising above an adjacent portion of an adjacent ridge with which the trough is associated.

33. A system for generating laser radiation comprising:
a discharge chamber;
a first electrode positioned at least partially within the discharge chamber; and
a second electrode positioned at least partially within the discharge chamber, the first electrode having a first discharge surface and the second electrode having a second discharge surface, the first discharge surface and the second discharge surface being arranged to confront one another across a gap;
wherein at least one of the first discharge surface and the second discharge surface comprises a distribution of a plurality of engineered discharge nucleation sites.

34. The system of claim 33 wherein the first electrode is connected to function as a cathode and wherein the first discharge surface comprises the distribution of a plurality of engineered discharge nucleation sites.

35. The system of claim 33 wherein the first discharge surface comprises a plurality of engineered indentations each having an edge and wherein each of the engineered nucleation sites comprises at least a portion of the edge of an associated one of the engineered indentations.

36. The system of claim 35 wherein the engineered indentations have a depth in the range of about 10 μm to about 1000 μm.

37.-41. canceled

42. A method of making a discharge electrode for a laser discharge chamber, the method comprising:
providing an electrode having a discharge surface; and
creating a distribution of a plurality of engineered discharge nucleation sites on the discharge surface.

43. The method of claim 42 wherein creating a distribution of a plurality of engineered discharge nucleation sites on the discharge surface comprises laser drilling, chemical etching, plasma etching, mechanically drilling, or mechanically indenting the engineered discharge nucleation sites.

44.-47. canceled
